(19) United States
(12) Patent Application Publication
(10) Pub. No.: US 2007/0141843 A1
(43) Pub. Date: Jun. 21, 2007

(54) SUBSTRATE PERIPHERAL FILM-REMOVING APPARATUS AND SUBSTRATE PERIPHERAL FILM-REMOVING METHOD

(75) Inventors: Eiichi Nishimura, Nirasaki-shi (JP); Kaoru Maekawa, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/564,662

(22) Filed: Nov. 29, 2006

Related U.S. Application Data
(60) Provisional application No. 60/754,629, filed on Dec. 30, 2005.

(30) Foreign Application Priority Data
Dec. 1, 2005 (JP) 2005-347981

(51) Int. Cl. C23F 1/00; H01L 21/302; C03C 25/68

(52) U.S. Cl. 438/689; 156/345.3; 216/58

(57) ABSTRACT

A substrate peripheral film-removing apparatus which is capable of removing a film from a substrate periphery without complicating the construction of the apparatus. A wafer chamber receives a wafer having an SiO₂ film formed on a periphery thereof. In a beveled portion-receiving chamber, film-removing chemical processing is carried out on at least part of the beveled portion of the wafer, using a process gas.

### BACKGROUND OF THE INVENTION

1. Field of the Invention

The present invention relates to a substrate peripheral film-removing apparatus and a substrate peripheral film-removing method, and more particularly to a substrate peripheral film-removing apparatus that removes a film from a substrate periphery without using plasma and a substrate peripheral film-removing method therefor.

2. Description of the Related Art

Semiconductor devices are manufactured by forming gate electrodes, insulating films, wiring layers, etc. on a silicon wafer (hereinafter simply referred to as “the wafer”) . The gate electrodes, the insulating films, and the wiring layers are formed by deposition and etching. For example, RIE (Reactive Ion Etching) is suitably used particularly for removing a SiO₂ film from the gate electrodes and source/drain portions formed on the wafer to form contact holes.

In general, semiconductor devices are not made from a peripheral portion (hereinafter referred to as “the beveled portion”) of a wafer. An SiO₂ film on the beveled portion is removed together with an SiO₂ film on gate electrodes by etching during formation of contact holes. Therefore, during the process of removing the SiO₂ film from the gate electrodes, a large amount of SiO₂ film remains on the beveled portion. The SiO₂ film on the beveled portion is not covered with a resist film, and hence it is directly exposed to plasma and charged by electrons and the like in the plasma. At this time, a direction in which ions travel for etching the SiO₂ film on the gate electrodes is bent by the influence of electric charge of the charged SiO₂ film on the beveled portion, which hinders the contact holes from being accurately formed vertically with respect to the surface of the wafer.

To solve this problem, a method has been developed in which the SiO₂ film on the beveled portion of a wafer is removed in advance by etching (see e.g. Japanese Laid-Open Patent Publication (Kokai) No. H10-256163). This method employs RIE or radical sputtering, as the etching technique.

However, in order to carry out RIE or radical sputtering, it is required to generate plasma in the vicinity of the wafer, and this inevitably complicates the construction of a film-removing apparatus for removing the SiO₂ film from the beveled portion.

### SUMMARY OF THE INVENTION

It is an object of the present invention to provide a substrate peripheral film-removing apparatus and a substrate peripheral film-removing method, which are capable of removing a film from a substrate periphery without complicating the construction of the apparatus.

To attain the above object, in a first aspect of the present invention, there is provided a substrate peripheral film-removing apparatus comprising a receiving chamber that receives a substrate having a film formed on a periphery thereof, and a chemical processing device that carries out film-removing chemical processing on at least part of the periphery of the substrate, using a process gas.

With the arrangement of the first aspect of the present invention, the substrate having the film formed on the periphery thereof is received in the receiving chamber, and film-removing chemical processing is carried out on at least part of the periphery of the substrate using a process gas. Therefore, it is not necessary to use RIE or radical sputtering to remove the film from the substrate periphery, which makes it possible to remove the film from the substrate periphery without complicating the construction of the apparatus.

Preferably, the chemical processing device includes an isolation chamber that receives at least part of the periphery to isolate the part from an atmosphere in the receiving chamber, and a process gas supply device that supplies the process gas into the isolation chamber, and the substrate peripheral film-removing apparatus further comprises a heating device that heats the part of the periphery received in the isolation chamber.

With the arrangement of this preferred embodiment, at least part of the periphery is received in the isolation chamber so as to be isolated from the atmosphere in the receiving chamber. Then, the process gas is supplied into the isolation chamber and the part of the periphery received in the isolation chamber is heated. This makes it possible to promote removal of the film from the substrate periphery without deteriorating or removing films formed on portions other than the substrate periphery.

Preferably, the film is an oxide film, and the process gas contains at least one gas selected from the group consisting of hydrogen fluoride gas, hydrochloric acid gas, fluorine gas, chlorine gas, and ammonia gas.

With the arrangement of this preferred embodiment, the film is an oxide film, and the process gas contains at least one gas selected from the group consisting of hydrogen fluoride gas, hydrochloric acid gas, fluorine gas, chlorine gas, and ammonia gas. Hydrogen fluoride gas, hydrochloric acid gas, fluorine gas, chlorine gas, and ammonia gas are easily available, and the oxide film can be easily removed by hydrogen fluoride gas, hydrochloric acid gas, fluorine gas, chlorine gas, or ammonia gas. Therefore, it is easy to remove the film from the substrate periphery.

Preferably, the receiving chamber is filled with an inert gas, and a pressure in the receiving chamber is higher than a pressure in the isolation chamber.

With the arrangement of this preferred embodiment, the receiving chamber is filled with an inert gas, and the pressure in the receiving chamber is higher than that in the isolation chamber. Therefore, it is possible to positively prevent the process gas from leaking from the isolation chamber and deteriorating or removing the film formed on the portions other than the substrate periphery.

Preferably, the substrate peripheral film-removing apparatus comprises a mounting stage on which the substrate is mounted and which rotates the substrate in a plane parallel with a surface of the substrate, in the receiving chamber, and the mounting stage includes a cooling device for cooling the substrate.

With the arrangement of this preferred embodiment, the substrate is rotated in a plane parallel with the surface of the substrate, and cooled. This makes it possible not only to positively remove the film formed on the substrate periphery from the entire periphery along the circumference of the substrate, but also to prevent semiconductor devices formed on the portions other than the substrate periphery from being damaged by heating performed for film removal.

To attain the above object, in a second aspect of the present invention, there is provided a substrate peripheral film-removing apparatus comprising a receiving chamber that receives a substrate having a film formed on a periphery thereof, and a film-removing chamber that receives at least part of the periphery to isolate the part from an atmosphere in the receiving chamber, and removes the film from the isolated part of the periphery.

With the arrangement of the second aspect of the present invention, in a state where the substrate having the film formed on the periphery thereof is received in the receiving chamber, and at least part of the periphery of the substrate is received in the film-removing chamber so as to be isolated from the atmosphere in the receiving chamber, the film on the isolated part of the periphery is removed. In doing this, the process gas for removing the film is introduced into the film-removing chamber, which makes it unnecessary to perform RIE or radical sputtering to remove the film from the substrate periphery, and hence it is possible to remove the film from the substrate periphery without complicating the construction of the apparatus.

To attain the above object, in a third aspect of the present invention, there is provided a method of removing a substrate peripheral film, comprising a substrate-receiving step of receiving a substrate having a film formed on a periphery thereof into a receiving chamber, and a film-removing step of carrying out film-removing chemical processing on at least part of the periphery of the substrate using a process gas.

Preferably, the method includes an isolation step of receiving at least part of the periphery in an isolation chamber to isolate the part from an atmosphere in the receiving chamber, a process gas supply step of supplying the process gas into the isolation chamber, and a heating step of heating the part of the periphery received in the isolation chamber.

Preferably, the method includes a substrate-rotating step of rotating the substrate in a plane parallel with a surface of the substrate, and a cooling step of cooling the substrate.

To attain the above object, in a fourth aspect of the present invention, there is provided a method of removing a substrate peripheral film, comprising a substrate-receiving step of receiving a substrate having a film formed on a periphery thereof into a receiving chamber, and an isolation step of receiving at least part of the periphery to isolate the part from an atmosphere in the receiving chamber, and a film-removing step of removing the film from the isolated part of the periphery.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate an embodiment of the present invention and, together with the description, serve to explain the principles of the present invention.

FIG. 1 is a schematic cross-sectional view of a wafer beveled portion oxide film-removing unit as a substrate peripheral film-removing apparatus according to a first embodiment of the present invention;

FIG. 2 is a cross-sectional view taken on line II-II of FIG. 1;

FIG. 3 is a flowchart of the wafer beveled portion oxide film-removing process carried out using the wafer beveled portion oxide film-removing unit shown in FIG. 1;

FIGS. 4A to 4C constitute a process diagram showing process steps for removing an SiO₂ film from a wafer beveled portion by the process shown in FIG. 3, in which FIG. 4A shows the wafer beveled portion before removal of the SiO₂ film, FIG. 4B shows the wafer beveled portion after removal of the SiO₂ film, and FIG. 4C shows the wafer beveled portion after formation of contact holes and removal of a resist film;

FIG. 5 is a schematic cross-sectional view of a wafer beveled portion oxide film-removing unit as a substrate peripheral film-removing apparatus according to a second embodiment of the present invention;

FIG. 6 is a cross-sectional view taken on line VI-VI of FIG. 5.

### DETAILED DESCRIPTION OF THE PREFERRED EMBODIMENTS

Preferred embodiments of the present invention will be described in detail below with reference to the drawings.

First, a description will be given of a substrate peripheral film-removing apparatus according to a first embodiment of the present invention.

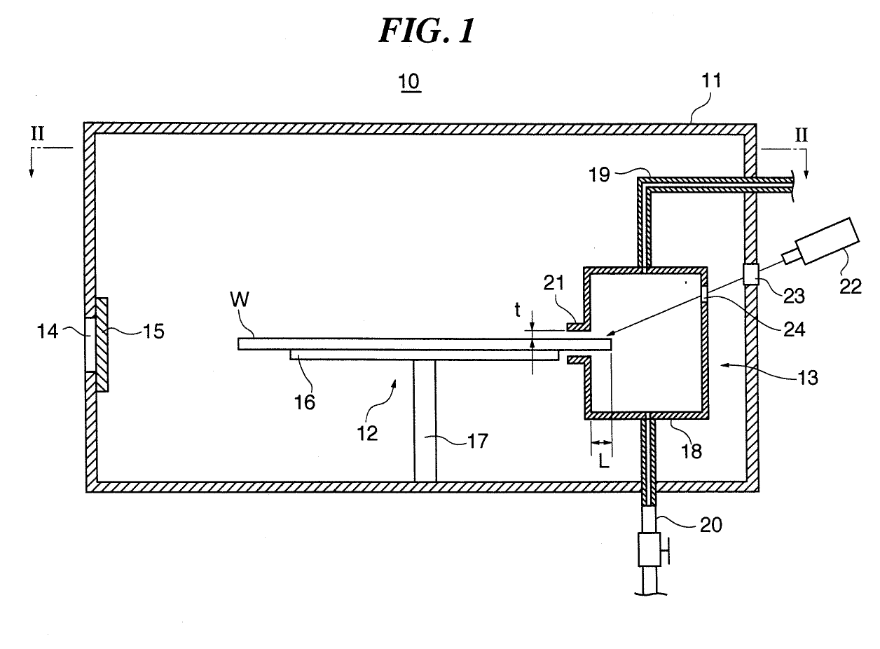

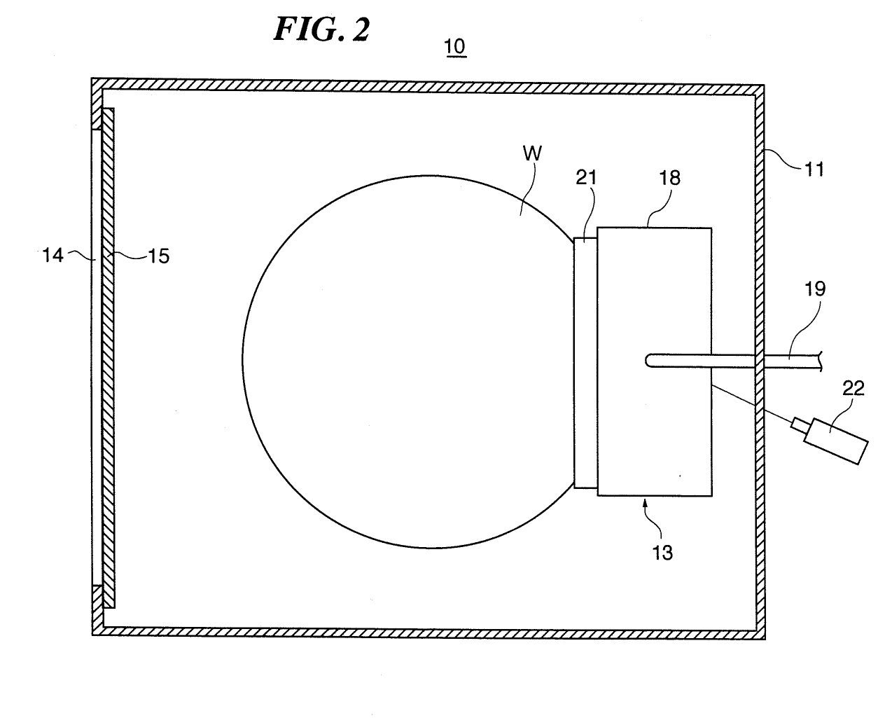

FIG. 1 is a schematic cross-sectional view of a wafer beveled portion oxide film-removing unit as the substrate peripheral film-removing apparatus according to the present embodiment. FIG. 2 is a cross-sectional view taken on line II-II of FIG. 1.

As shown in FIGS. 1 and 2, the wafer beveled portion oxide film-removing unit 10 is comprised of a wafer chamber 11 (receiving chamber) for receiving a wafer W to isolate the same from the outside, a wafer stage 12 (mounting stage) disposed in the wafer chamber 11, for mounting or placing the wafer W thereon, and a beveled portion-receiving chamber 13 (chemical processing unit, film-removing chamber) for receiving part of a beveled portion of the wafer W placed on the wafer stage 12 to thereby isolate the part of the beveled portion from the atmosphere in the wafer chamber 11. On the beveled portion of the wafer W is formed an oxide film, such as an SiO₂ film, functioning as an insulating layer of a semiconductor device.

The wafer chamber 11 has a side wall thereof formed with a wafer inlet/outlet port 14, which is opened and closed by a gate valve 15. The wafer stage 12 is comprised of a disk-shaped wafer mounting plate 16 disposed horizontally substantially in parallel with a bottom surface of the wafer chamber 11, and a mounting plate support shaft 17 that extends downward from the center of the wafer mounting plate 16 and supports the wafer mounting plate 16. The mounting plate support shaft 17 is driven e.g. by a motor, not shown, for rotation about its axis, and hence the wafer stage 12 rotates about the axis of the mounting plate support shaft 17. As a consequence, the wafer stage 12 causes the wafer W to rotate in a plane parallel with the surface of the wafer W placed thereon. Further, the wafer mounting plate 16 incorporates a cooling device, not shown, such as a refrigerant recirculation passage or a Peltier element, and controls the temperature of the wafer W mounted thereon.

The beveled portion-receiving chamber 13 is comprised of a rectangular parallelepiped process chamber 18 (isolation chamber, film-removing chamber), a process gas supply pipe 19 through which a process gas, referred to hereinafter, is supplied to the process chamber 18, an exhaust gas pipe 20 through which gases and the like are exhausted from the process chamber 18, and a protruding opening 21 that protrudes from a side wall of the process chamber 18 and opens toward the wafer W mounted on the wafer stage 12. The protruding opening 21 is comprised of two plate-shaped parts protruding in parallel with each other as eaves toward the wafer W from the side wall of the process chamber 18.

The height of the protruding opening 21 is set such that the protruding opening 21 is opposed to the wafer W mounted on the wafer stage 12, and, as shown in FIG. 2, the beveled portion-receiving chamber 13 is disposed in a manner overlapping the beveled portion of the wafer W in plan view. Therefore, the beveled portion-receiving chamber 13 receives part of the beveled portion of the wafer W, and the received part of the beveled portion of the wafer W protrudes into the process chamber 18 via the protruding opening 21. This causes the process chamber 18 to isolate the received part of the beveled portion of the wafer W from the atmosphere within the wafer chamber 11.

The wafer beveled portion oxide film-removing unit 10 includes a laser beam irradiation device 22 (heating device) disposed outside the wafer chamber 11. A laser beam emitted from the laser beam irradiation device 22 passes through a transmission window 23 formed in the side wall of the wafer chamber 11 and a transmission window 24 formed in the side wall of the process chamber 18 to reach the beveled portion of the wafer W received in the process chamber 18. With this configuration, the laser beam irradiation device 22 heats the beveled portion of the wafer W.

The process gas supply pipe 19 is connected to a process gas supply unit, not shown, via an MFC (Mass Flow Controller), not shown, and the process gas supply unit and the MFC supply an active gas, such as hydrogen fluoride (HF) gas, hydrochloric acid (HCl) gas, fluorine (F₂) gas, chlorine (Cl₂) gas, or ammonia (NH₃) gas, or a mixture gas composed of some of these gases to the process chamber 18 at a predetermined flow rate. The HF gas or the like supplied into the process chamber 18 removes the SiO₂ film from the beveled portion by chemical reaction. At this time, the beveled portion of the wafer W is irradiated with a laser beam, thereby raising the temperature of the beveled portion, which promots the removal of the SiO₂ film from the beveled portion by chemical reaction.

The beveled portion-receiving chamber 13 receives only part of the beveled portion of the wafer W as described above. However, since the wafer W rotates in the plane parallel with its surface, it is possible to positively remove the SiO₂ film from the entire beveled portion along the circumference of the waver W. An amount L of protrusion of the wafer W into the process chamber 18 is set to 2 mm or less. In general, semiconductor devices are not formed within a range of 2 mm extending inward from the peripheral edge of a wafer. Therefore, the semiconductor devices on the wafer W can be prevented from being damaged by the active gas during removal of the SiO₂ film from the beveled portion of the wafer W.

A clearance (t) between the wafer W and each of the plate-shaped members of the protruding opening 21 is set to 0.5 mm or less. Further, the wafer chamber 11 is filled with an inert gas, such as a rare gas, and the pressure in the wafer chamber 11 is set higher than that in the process chamber 18. This makes it possible to prevent the process gas in the process chamber 18 from flowing into the wafer chamber 11, thereby positively preventing deterioration or removal of the SiO₂ film formed on portions of the wafer W other than the beveled portion.

When the beveled portion is heated for removal of the SiO₂ film therefrom, the cooling device contained in the wafer mounting plate 16 of the wafer stage 12 cools the wafer W, and therefore the semiconductor devices on the wafer W can be prevented from being damaged by the heat.

Next, a description will be given of a process of removing oxide film from the beveled portion of a wafer W using the wafer beveled portion oxide film-removing unit 10.

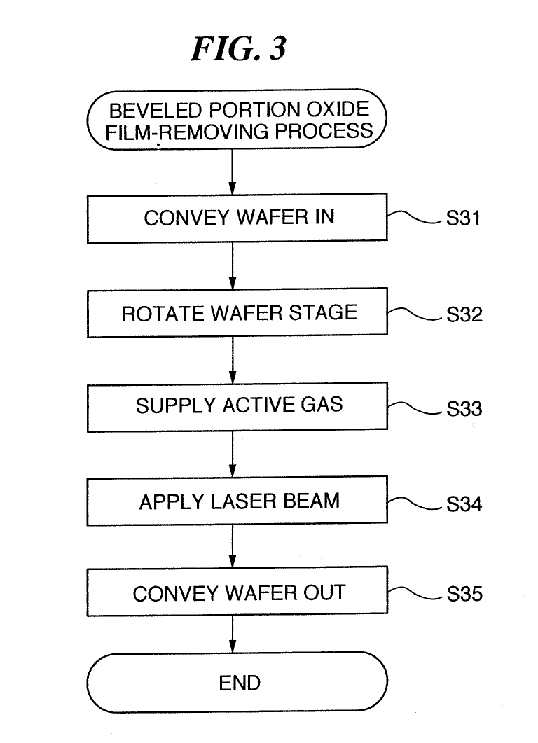

FIG. 3 is a flowchart of the wafer beveled portion oxide film-removing process carried out using the wafer beveled portion oxide film-removing unit 10 shown in FIG. 1.

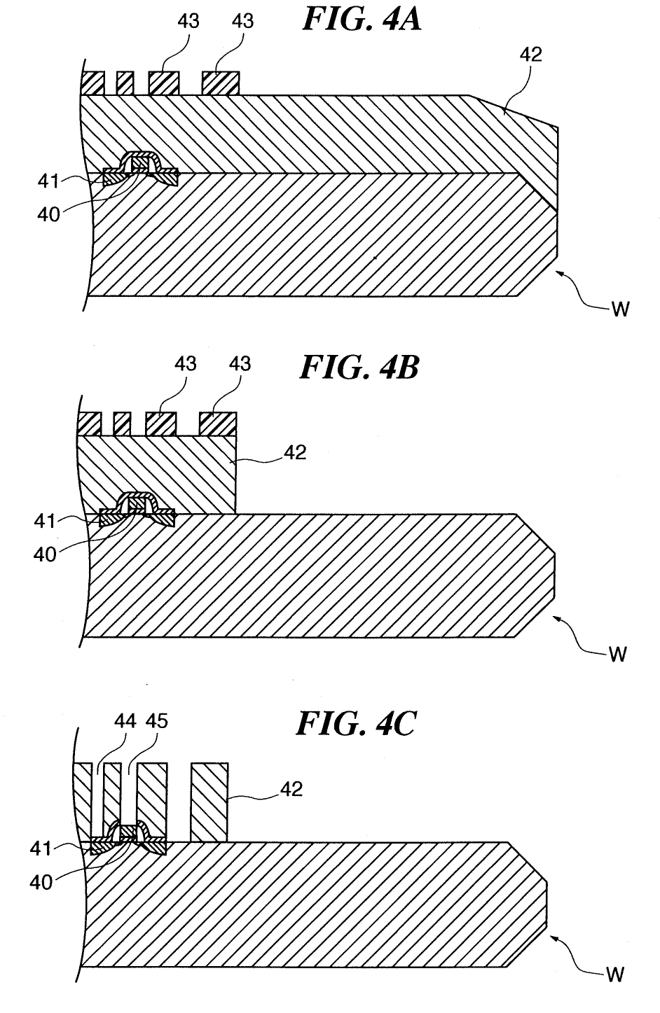

As shown in FIG. 3, first, a wafer W is conveyed into the wafer chamber 11 e.g. by a conveyor arm, not shown, and is placed on the wafer stage 12, while causing part of the beveled portion thereof to be received in the process chamber 18 of the beveled portion-receiving chamber 13 (step S31). At this time, as shown in FIG. 4A, gate electrodes 40 and source/drain portions 41 have been formed on the wafer W conveyed in, and an SiO₂ film 42 has been formed on the wafer W in a manner covering the entire surface of the same. Further, a resist film 43 formed in a predetermined pattern e.g. by lithography has been formed on the SiO₂ film 42. It should be noted that the resist film 43 has not been formed on the SiO₂ film 42 on the beveled portion, and hence the SiO₂ film 42 on the beveled portion is exposed.

Next, the mounting plate support shaft 17 of the wafer stage 12 is driven for rotation e.g. by the motor to cause rotation of the wafer stage 12 (step S32), and the process gas supply unit and the MFC supply the above-mentioned active gas into the process chamber 18 at the predetermined flow rate (step S33). Further, the laser beam irradiation device 22 starts irradiating the beveled portion received in the process chamber 18 with a laser beam to thereby heat the beveled portion (step S34). This causes the SiO₂ film 42 to be removed from the beveled portion by chemical reaction.

Then, when the SiO₂ film 42 is removed from the entire beveled portion of the wafer W as shown in FIG. 4B, the rotation of the wafer stage 12, the supply of the active gas by the process gas supply unit, and the irradiation of the laser beam by the laser beam irradiation device 22 are all stopped. Thereafter, the conveyor arm conveys the wafer W out of the wafer chamber 11 (step S35), followed by terminating the present process.

After having processed in the wafer chamber 11, the wafer W is conveyed into an etching unit, not shown, and the SiO₂ film 42 is removed from the gate electrodes 40 and the source/drain portions 41 e.g. by RIE, whereby contact holes 44 and 45 are formed. Further, the wafer W is conveyed into an ashing unit, not shown, where the resist film 43 is removed by ashing (see FIG. 4C).

According to the wafer beveled portion oxide film-removing unit 10 and the beveled portion oxide film-removing process shown in FIG. 3, the wafer W having the SiO₂ film 42 formed on the beveled portion thereof is received in the wafer chamber 11, and the SiO₂ film 42 is removed from the beveled portion by chemical reaction using the active gas. Therefore, it is not necessary to use RIE or radical sputtering to remove the SiO₂ film 42 from the beveled portion, which makes it possible to remove the SiO₂ film 42 from the beveled portion without complicating the construction of the oxide film-removing unit. Further, part of the beveled portion is received in the process chamber 18 within the beveled portion-receiving chamber 13 so as to be isolated from the atmosphere in the wafer chamber 11, and the active gas is supplied into the process chamber 18. Then, the part of the beveled portion received in the process chamber 18 is heated. This makes it possible to promote removal of the SiO₂ film 42 from the beveled portion without deteriorating or removing the SiO₂ film 42 formed on portions other than the beveled portion.

In the wafer beveled portion oxide film-removing unit 10, hydrogen fluoride gas, hydrochloric acid gas, fluorine gas, chlorine gas, or ammonia gas, or a mixture gas composed of some of these gases is used as the active gas. These gases are easily available, and the SiO₂ film can be easily removed by hydrogen fluoride gas, hydrochloric acid gas, fluorine gas, chlorine gas, or ammonia gas. Therefore, the SiO₂ film 42 can be easily removed from the beveled portion.

Although in the wafer beveled portion oxide film-removing unit 10, the laser beam irradiation device 22 heats the beveled portion of the wafer W, this is not limitative, but a UV heater, a halogen lamp, or the like may be provided in the process chamber 18 to heat the beveled portion.

Next, a description will be given of a substrate peripheral film-removing apparatus according to a second embodiment of the present invention.

The present embodiment has basically the same construction and effects as those of the above-described first embodiment, and is distinguished from the first embodiment only in that COR processing and PHT processing, referred to hereinafter, are used to remove the SiO₂ film 42 from the beveled portion of the wafer W, and that there are provided two beveled portion-receiving chambers for carrying out the COR processing and the PHT processing. Therefore, duplicate description of the construction and effects is omitted, and only different points of the construction and effects of the present embodiment from those of the first embodiment will be described hereafter.

In the COR processing, an oxide film (e.g. SiO₂ film formed on a wafer) is caused to undergo chemical reaction with gas molecules to produce a product, and in the PHT processing, the wafer having undergone the COR processing is heated so as to cause the product produced on the wafer to undergo vaporization and thermal oxidation to remove the product from the wafer. As described above, the COR processing and the PHT processing remove the oxide film on the wafer without using plasma or water, and hence are categorized as plasma-less etching or dry cleaning.

In the substrate peripheral film-removing apparatus according to the present embodiment, radicalized ammonia gas and hydrogen fluoride gas are used as a process gas. Here, the hydrogen fluoride gas promotes corrosion of SiO₂ film, and the ammonia gas is involved in synthesis of a reaction by-product for restricting, as required, and ultimately stopping the reaction between the SiO₂ film and the hydrogen fluoride gas. More specifically, the COR processing and the PHT processing utilize the following chemical reactions:

(COR PROCESSING)
SiO₂+4HF→SiF₄+2H₂O_{↑}
SiF₄+2NH₃+2HF→(NH₄)₂SiF₆
(PHT PROCESSING)
(NH₄)₂SiF₆→SiF_{4↑}+2NH_{3↑}+2HF_{↑}

It is known that in the COR processing utilizing the above-mentioned chemical reactions, the amount of production of the product levels off upon the lapse of certain time. Specifically, once the certain time has elapsed, even if the SiO₂ film continues to be exposed to the mixed gas of ammonia gas and hydrogen fluoride gas beyond this, there is no further increase in the amount of production of the product. Moreover, the amount of production of the product is determined by the pressure of the ammonia gas and the hydrogen fluoride gas, the volumetric flow rate, and so forth. Therefore, it is possible to easily control the amount of removal of the SiO₂ film, thereby preventing the silicon of the wafer from being damaged.

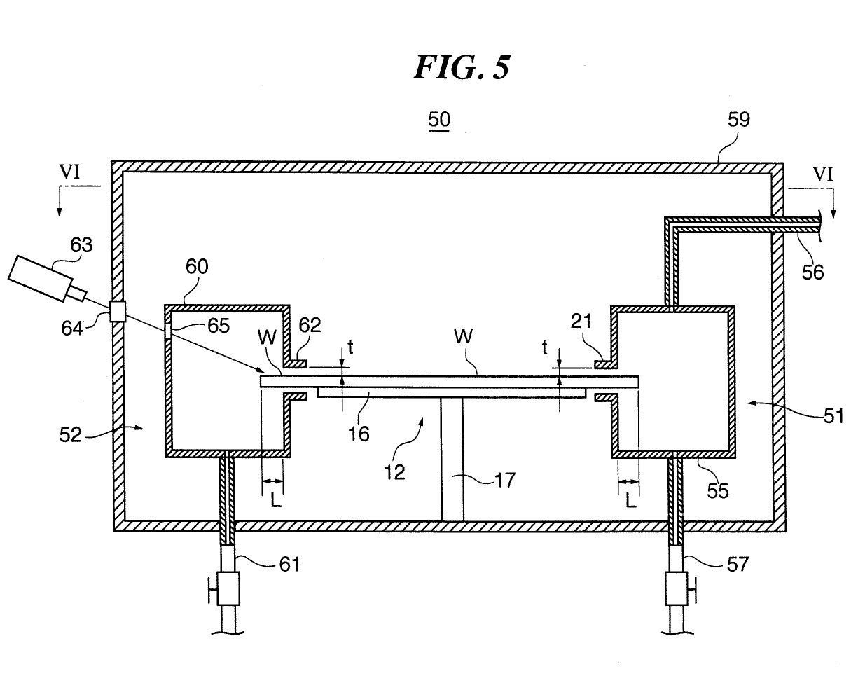

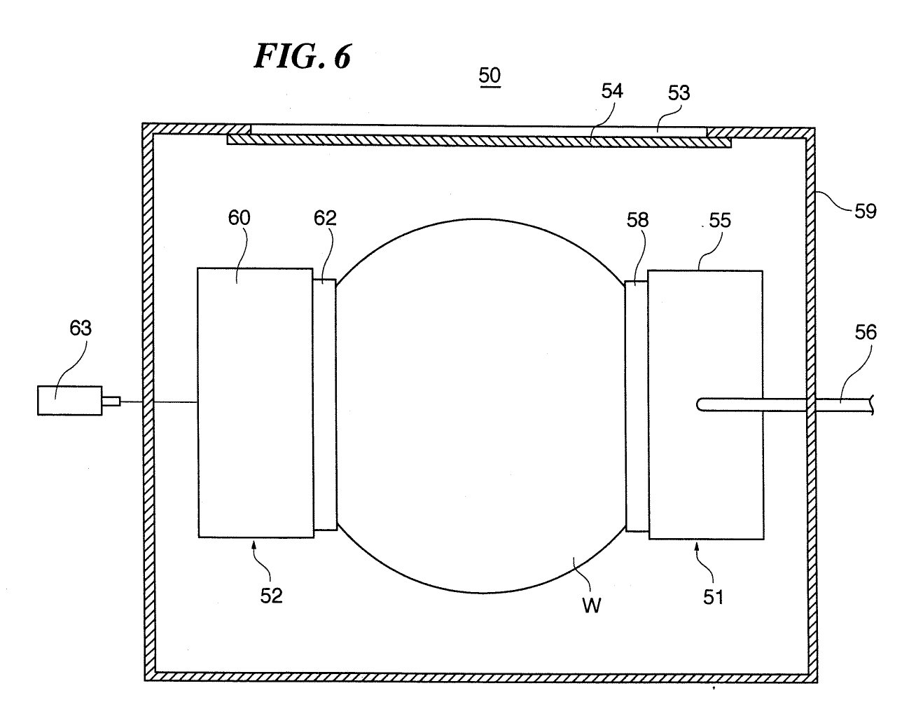

FIG. 5 is a schematic cross-sectional view of a wafer beveled portion oxide film-removing unit as the substrate peripheral film-removing apparatus according to the present embodiment. FIG. 6 is a cross-sectional view taken on line VI-VI of FIG. 5.

As shown in FIGS. 5 and 6, the wafer beveled portion oxide film-removing unit 50 is comprised of a wafer chamber 59 (receiving chamber), the wafer stage 12, and the two beveled portion-receiving chambers 51 and 52 (chemical processing devices) each for receiving part of the beveled portion of the wafer W placed on the wafer stage 12 to thereby isolate the received part of the beveled portion from the atmosphere in the wafer chamber 59. The wafer chamber 59 has a side wall thereof formed with a wafer inlet/outlet port 53, which is opened and closed by a gate valve 54.

The beveled portion-receiving chamber 51 is comprised of a rectangular parallelepiped process chamber 55 (isolation chamber), a process gas supply pipe 56 through which radicalized ammonia gas and hydrogen fluoride gas are supplied into the process chamber 55, an exhaust gas pipe 57 through which gases and the like are exhausted from the process chamber 55, and a protruding opening 58 that protrudes from a side wall of the process chamber 55 and opens toward the wafer W placed on the wafer stage 12. The protruding opening 58 has the same eaves as those of the protruding opening 21 in FIG. 1.

The beveled portion-receiving chamber 52 is comprised of a rectangular parallelepiped process chamber 60 (film-removing chamber), an exhaust gas pipe 61 through which gases and the like are exhausted from the process chamber 60, and a protruding opening 62 that protrudes from a side wall of the process chamber 60 and opens toward the wafer W disposed on the wafer stage 12. The protruding opening 62 also has the same eaves as those of the protruding opening.

The wafer beveled portion oxide film-removing unit 50 includes a laser beam irradiation device 63 (heating device) disposed outside the wafer chamber 59. A laser beam emitted from the laser beam irradiation device 63 passes through a transmission window 64 formed in a side wall of the wafer chamber 59 and a transmission window 65 formed in a side wall of the process chamber 60 to reach the beveled portion of the wafer W received in the process chamber 60. With this configuration, the laser beam irradiation device 63 heats the beveled portion of the wafer W.

The height of the protruding openings 58 and 62 is set such that protruding openings 58 and 62 are opposed to the wafer W mounted on the wafer stage 12, and, as shown in FIG. 6, the beveled portion-receiving chambers 51 and 52 are each disposed in a manner overlapping part of the beveled portion of the wafer W in plan view. Therefore, each of the beveled portion-receiving chambers 51 and 52 receives part of the beveled portion of the wafer W, and the received part of the beveled portion of the wafer W protrudes into the process chambers 51 and 52 via the protruding openings 58 and 62, respectively. This causes the process chambers 55 and 60 to isolate the received part of the beveled portion of the wafer W from the atmosphere within the wafer chamber 59.

The process gas supply pipe 56 of the beveled portion-receiving chamber 51 is connected to a process gas supply unit, not shown, via an MFC, not shown, and the process gas supply unit and the MFC supply radicalized ammonia gas and hydrogen fluoride gas to the process chamber 55 at a predetermined flow rate. The COR processing is carried out on the beveled portion of the wafer W using the radicalized ammonia gas and hydrogen fluoride gas supplied into the process chamber 55. At this time, a product is produced from the SiO₂ film, the ammonia gas, and the hydrogen fluoride gas.

The beveled portion-receiving chamber 52 receives the beveled portion having the product produced thereon by the COR processing, and the laser beam irradiation device 63 heats the beveled portion of the wafer W (PHT processing). Through this processing, the product on the beveled portion is vaporized and thermally oxidized to be removed from the wafer. This removes the SiO₂ film from the beveled portion.

Each of the beveled portion-receiving chambers 51 and 52 receives only part of the beveled portion of the wafer W as described above. However, since the wafer W rotates in the plane parallel with its surface, it is possible to positively remove the SiO₂ film from the entire beveled portion along the circumference of the wafer W. Further, as is the case with the wafer beveled portion oxide film-removing unit 10, the amount L of protrusion of the wafer W into the process chambers 55 and 60 is set to 2 mm or less, and the clearance (t) between the wafer W and the inner surface of each of the protruding openings 58 and 62 is set to 0.5 mm or less. The wafer chamber 59 is filled with an inert gas, such as a rare gas, and the pressure in the wafer chamber 11 is set higher than those in the process chambers 55 and 60.

When the beveled portion is heated so as to vaporize and thermally oxidize the product on the beveled portion, the cooling device contained in the wafer mounting plate 16 of the wafer stage 12 cools the wafer W. This makes it possible to prevent the semiconductor devices on the wafer W from being damaged by the heat.

According to the wafer beveled portion oxide film-removing unit 50, the wafer W having the SiO₂ film 42 formed on the beveled portion thereof is received in the wafer chamber 59, where the SiO₂ film 42 is removed from the beveled portion by the COR processing and the PHT processing. Therefore, it becomes unnecessary to execute RIE or radical sputtering to remove the SiO₂ film 42 from the beveled portion, which makes it possible to remove the SiO₂ film 42 from the beveled portion without complicating the construction of the oxide film-removing unit.

Further, part of the beveled portion is received in the process chamber 55 of the beveled portion-receiving chamber 51 so as to be isolated from the atmosphere in the wafer chamber 59, and the radicalized ammonia gas and hydrogen fluoride gas are supplied into the process chamber 55, whereby the COR processing is carried out on the beveled portion. Then, the beveled portion having a product produced from the SiO₂ film 42 by the COR processing is received in the process chamber 60 of the beveled portion-receiving chamber 52, and the received part of the beveled portion is heated (i.e. subjected to the PHT processing), whereby the product is vaporized and thermally oxidized. This makes it possible to remove the SiO₂ film 42 from the beveled portion without deteriorating or removing the SiO₂ film 42 formed on portions other than the beveled portion.

Although in the wafer beveled portion oxide film-removing units according to the above-described embodiments, the oxide film (SiO₂ film) formed on the beveled portion of the wafer W is removed, this is not limitative, but an insulating film charged by electrons or the like may be removed. Further, the wafer beveled portion oxide film-removing unit may be used to remove a deposit deposited on the wafer W.

The above-described embodiments are merely exemplary of the present invention, and are not be construed to limit the scope of the present invention.

The scope of the present invention is defined by the scope of the appended claims, and is not limited to only the specific descriptions in this specification. Furthermore, all modifications and changes belonging to equivalents of the claims are considered to fall within the scope of the present invention.

What is claimed is:

1. A substrate peripheral film-removing apparatus comprising:
a receiving chamber that receives a substrate having a film formed on a periphery thereof; and
a chemical processing device that carries out film-removing chemical processing on at least part of the periphery of the substrate, using a process gas.

2. A substrate peripheral film-removing apparatus as claimed in claim 1, wherein said chemical processing device includes an isolation chamber that receives at least part of the periphery to isolate the part from an atmosphere in said receiving chamber, and a process gas supply device that supplies the process gas into said isolation chamber,
the substrate peripheral film-removing apparatus further comprising a heating device that heats the part of the periphery received in said isolation chamber.

3. A substrate peripheral film-removing apparatus as claimed in claim 1, wherein the film is an oxide film, and the process gas contains at least one gas selected from the group consisting of hydrogen fluoride gas, hydrochloric acid gas, fluorine gas, chlorine gas, and ammonia gas.

4. A substrate peripheral film-removing apparatus as claimed in claim 1, wherein said receiving chamber is filled with an inert gas, and a pressure in said receiving chamber is higher than a pressure in said isolation chamber.

5. A substrate peripheral film-removing apparatus as claimed in claim 1, comprising a mounting stage on which the substrate is mounted and which rotates the substrate in a plane parallel with a surface of the substrate, in said receiving chamber, and
wherein said mounting stage includes a cooling device for cooling the substrate.

6. A substrate peripheral film-removing apparatus comprising:
a receiving chamber that receives a substrate having a film formed on a periphery thereof; and
a film-removing chamber that receives at least part of the periphery to isolate the part from an atmosphere in said receiving chamber, and removes the film from the isolated part of the periphery.

7. A method of removing a substrate peripheral film, comprising:
a substrate-receiving step of receiving a substrate having a film formed on a periphery thereof into a receiving chamber; and
a film-removing step of carrying out film-removing chemical processing on at least part of the periphery of the substrate using a process gas.

8. A method as claimed in claim 7, including an isolation step of receiving at least part of the periphery in an isolation chamber to isolate the part from an atmosphere in the receiving chamber, a process gas supply step of supplying the process gas into the isolation chamber, and a heating step of heating the part of the periphery received in the isolation chamber.

9. A method as claimed in claim 7, including a substrate-rotating step of rotating the substrate in a plane parallel with a surface of the substrate, and a cooling step of cooling the substrate.

10. A method of removing a substrate peripheral film, comprising:
a substrate-receiving step of receiving a substrate having a film formed on a periphery thereof into a receiving chamber;
an isolation step of receiving at least part of the periphery to isolate the part from an atmosphere in the receiving chamber; and
a film-removing step of removing the film from the isolated part of the periphery.
